(19) United States
(12) Patent Application Publication
(10) Pub. No.: US 2026/0231689 A1
(43) Pub. Date: Aug. 6, 2026

(54) SUPERCONDUCTING DEVICE

(71) Applicant: KYOCERA Corporation, Kyoto-shi, Kyoto (JP)

(72) Inventors: Yuhei MATSUMOTO, Kirishima-shi, Kagoshima (JP); Sentarou YAMAMOTO, Kagoshima-shi, Kagoshima (JP); Takashi TANAKA, Kyoto-shi, Kyoto (JP); Natsuki OTA, Otsu-shi, Shiga (JP)

(73) Assignee: KYOCERA Corporation, Kyoto-shi, Kyoto (JP)

(21) Appl. No.: 19/131,437

(22) PCT Filed: Nov. 7, 2023
(86) PCT No.: PCT/JP2023/040114

§ 371 Date: May 20, 2025

(30) Foreign Application Priority Data
Nov. 21, 2022 (JP) 2022-185583

(51) Int. Cl. H10N 60/80; H10N 60/12

(52) U.S. Cl. CPC H10N 60/805; H10N 60/12

(57) ABSTRACT

A superconducting device according to the disclosure includes a superconducting element and a stage portion. The superconducting element is located at the stage portion. The stage portion is a laminate body of a ceramic layer and an organic layer.

### TECHNICAL FIELD

The disclosure relates to a superconducting device.

### BACKGROUND OF INVENTION

In the related art, a packaging technique for mounting a superconducting element such as a Josephson element is known. Patent Document 1 discloses a superconducting element mounting package in which a superconducting element such as the Josephson element is mounted on a substrate including an electrical conductor layer inserted between ceramic layers.

### CITATION LIST

### Patent Literature

Patent Document 1: JP H01-298608 A

### SUMMARY

A superconducting device according to an aspect of the disclosure includes a superconducting element and a stage portion. The superconducting element is located at the stage portion. The stage portion is a laminate body of a ceramic layer and an organic layer.

### BRIEF DESCRIPTION OF THE DRAWINGS

FIG. 1 is a schematic cross-sectional view illustrating a configuration example of a superconducting device according to a first embodiment.

FIG. 2 is a schematic cross-sectional view illustrating a configuration example of the superconducting device according to a second embodiment.

FIG. 3 is a schematic cross-sectional view illustrating a configuration example of the superconducting device according to a third embodiment.

FIG. 4 is a schematic cross-sectional view illustrating a configuration example of the superconducting device according to a fourth embodiment.

FIG. 5 is a schematic cross-sectional view illustrating a configuration example of the superconducting device according to a fifth embodiment.

FIG. 6 is a schematic plan view illustrating a positional relationship between an organic layer and a fixing member according to the fifth embodiment.

FIG. 7 is a schematic plan view illustrating a positional relationship between the organic layer and the fixing member according to a variation of the fifth embodiment.

FIG. 8 is a schematic cross-sectional view illustrating a configuration example of the superconducting device according to a sixth embodiment.

FIG. 9 is a schematic cross-sectional view illustrating a configuration example of the superconducting device according to a seventh embodiment.

FIG. 10 is a schematic cross-sectional view illustrating a configuration example of the superconducting device according to the seventh embodiment.

### DESCRIPTION OF EMBODIMENTS

Modes (hereinafter will be referred to as “embodiments”) for implementing a superconducting device according to the disclosure will be described in detail below with reference to the accompanying drawings. Note that the disclosure is not limited by the embodiments. Embodiments can be appropriately combined as long as the processing contents do not contradict each other. In the following embodiments, the same portions are denoted by the same reference signs, and redundant descriptions are omitted.

In the following embodiments, expressions such as “certain”, “orthogonal”, “perpendicular”, and “parallel” may be used, but these expressions need not mean exactly “certain”, “orthogonal”, “perpendicular”, and “parallel”. In other words, each of the expressions described above allows for deviations in, for example, manufacturing accuracy, or installation accuracy.

In the related art, a packaging technique for mounting a superconducting element such as a Josephson element is known. Patent Document 1 discloses a superconducting element mounting package in which a superconducting element such as the Josephson element is mounted on a substrate including an electrical conductor layer inserted between ceramic layers.

In order to obtain a superconducting state, such a superconducting element needs to be held in an atmosphere at a lower temperature than room temperature, for example, at about the boiling point (77K) of liquid nitrogen. However, in the package disclosed in Patent Document 1, since the substrate at which the superconducting element is mounted is made of a ceramic having a relatively high Young's modulus, when the superconducting element is cooled, a distortion due to a temperature change occurs in the substrate, which may cause cracks in the substrate.

A technique for reducing the occurrence of the cracks due to the temperature change is expected.

### First Embodiment

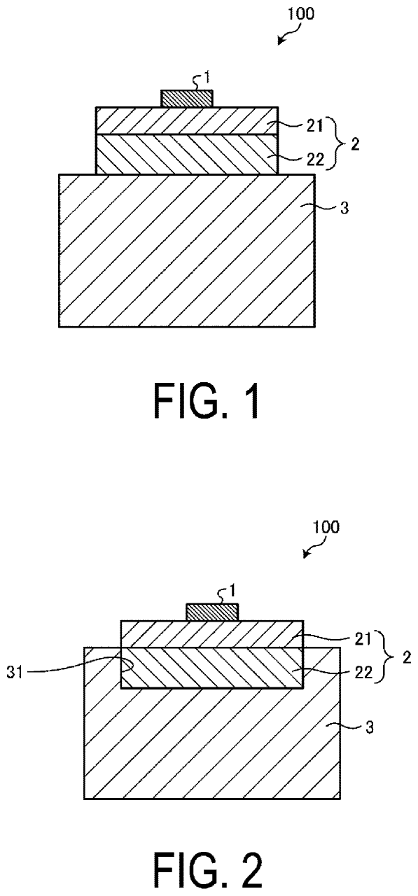

First, a configuration example of a superconducting device 100 according to a first embodiment will be described with reference to FIG. 1. FIG. 1 is a schematic cross-sectional view illustrating a configuration example of the superconducting device 100 according to the first embodiment. The superconducting device 100 is a device including a superconducting element 1. The superconducting device 100 is cooled to an extremely low temperature, for example, equal to or lower than the 4K, by using a refrigerant such as liquid helium in order to obtain a superconducting state by the superconducting element 1.

The superconducting device 100 includes the superconducting element 1, a stage portion 2, and a base 3. The superconducting element 1 is located at the stage portion 2. The stage portion 2 is a laminate body of a ceramic layer 22 and an organic layer 21. The ceramic layer 22 is located at the base 3 side described later. The organic layer 21 is located at the superconducting element 1 side.

The stage portion 2 may include, on a surface of the organic layer 21 and/or a surface of the ceramic layer 22, a conductor (not illustrated) extending in a direction along the surface. A configuration may also be adopted in which conductor materials are separated such that, for example, a superconducting material is disposed immediately below the superconducting element 1 and a normal conductive material (silver, gold, copper, or the like) is disposed around the superconducting material.

A shape of the stage portion 2 may have a circular shape or may be similar to a shape of the superconducting element 1 in a plan view. A surface of the stage portion 2 may have an uneven shape (not illustrated). In this case, a structure in which the superconducting element 1 is in contact with a protruding portion of the stage portion 2, in other words, a structure in which the superconducting element 1 is not in contact with a bottom of a recessed portion is preferable. In other words, the superconducting element 1 may be partially in contact with the stage portion 2. The recessed portions and the protruding portions are preferably arranged side by side alternately with each other. The recessed portions and the protruding portions may be continuously formed between end portions facing each other of the stage portion 2. When a conductor is disposed on the stage portion 2, VO/V1 is preferably from 10% to 50%, where V1 is the total volume of the conductor formed on the stage portion 2 and V0 is the total volume of the conductor penetrating through the stage portion 2.

When the conductor is disposed on the stage portion 2, part of the conductor may be formed by a meander wiring, a differential wiring, or the like. The stage portion 2 may partially include a metal film (not illustrated) to cope with a change in relative permittivity that occurs in a material of the stage portion 2 when the stage portion 2 is exposed to a temperature change from room temperature to an extremely low temperature. The impedance of a circuit can be adjusted by changing an electrostatic capacitance in the vicinity of a surface of the base 3 by the partially disposed metal film. Such a metal film does not contribute to an electric circuit.

When the stage portion 2 is constituted only by the ceramic layer 22 and the stage portion 2 is exposed to a low temperature, a stress is generated in the stage portion 2, and cracks may occur. As illustrated in FIG. 1, when the stage portion 2 includes the organic layer 21, the Young's modulus of the entire stage portion 2 can be reduced, and thus the occurrence of the cracks can be reduced.

Since the stage portion 2 is configured to dispose the ceramic layer 22 at the base 3 side, the ceramic layer 22 has a high Young's modulus even when the base 3 and the stage portion 2 have different coefficients of thermal expansion, and thus a strength of the stage portion 2 can be maintained. On the other hand, since the organic layer 21 is disposed at the superconducting element 1 side, a load (stress concentration) on the superconducting element 1 can be reduced eve when a distortion due to the coefficient of thermal expansion occurs in the stage portion 2.

The stage portion 2 is located at the base 3. The base 3 is made of a metal, for example.

The superconducting device 100 is connected to an external circuit (not illustrated) for driving the superconducting element 1. The external circuit is disposed outside the superconducting device 100 system. A temperature at a periphery at which the external circuit is disposed is a normal temperature of about 25° C.

As illustrated in FIG. 1, a thickness of the ceramic layer 22 may be greater than a thickness of the organic layer 21. According to such a configuration, since the thickness of the ceramic layer 22 is increased, the ceramic layer 22 is less likely to be deformed. Since a thickness of the organic layer 21 is reduced, the overall coefficient of thermal expansion of the stage portion 2 can be reduced. Thus, the load (stress) on the superconducting element 1 can be reduced, which leads to an improvement in mechanical reliability.

### Second Embodiment

FIG. 2 is a schematic cross-sectional view illustrating a configuration example of the superconducting device 100 according to a second embodiment. As illustrated in FIG. 2, the base 3 of the superconducting device 100 may include a recessed portion 31. In this case, the stage portion 2 may be located in the recessed portion 31. Specifically, the ceramic layer 22 of the stage portion 2 may be located in the recessed portion 31. According to such a configuration, a contact surface area between the stage portion 2 and the base 3 is increased, and the fixation becomes stronger. Since at least a bottom surface and a side surface of the ceramic layer 22 are in contact with the base 3, the heat dissipation efficiency is improved.

### Third Embodiment

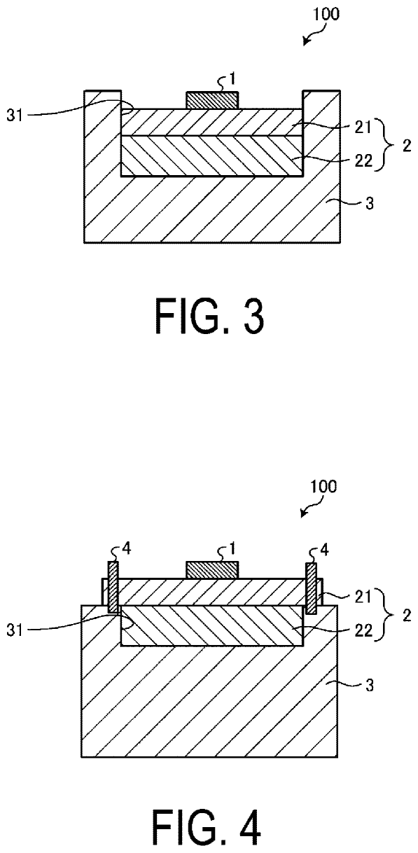

FIG. 3 is a schematic cross-sectional view illustrating a configuration example of the superconducting device 100 according to a third embodiment. As illustrated in FIG. 3, the entirety of the stage portion 2 of the superconducting device 100 may be accommodated in the recessed portion 31. According to such a configuration, a fixing force of the stage portion 2 to the base 3 can be further increased.

### Fourth Embodiment

FIG. 4 is a schematic cross-sectional view illustrating a configuration example of the superconducting device 100 according to a fourth embodiment. As illustrated in FIG. 4, the superconducting device 100 may include a fixing member 4 for fixing the organic layer 21 of the stage portion 2 and the base 3 to each other. The fixing member 4 may be, for example, a screw such as a bolt. The fixing member 4 may be a rod shape member such as a pin. According to such a configuration, since the base 3 and the organic layer 21 having a low rigidity are fixed to each other, the base 3 is hardly broken when the base 3 and the organic layer 21 are fixed to each other.

The fixing member 4 may include a washer material (not illustrated). As a member constituting the washer material, a member having a greater contraction rate than that of the fixing member 4 when the fixing member 4 is cooled is preferable. Since the fastening of the fixing member 4 becomes loose as the fixing member 4 is cooled, when the washer material is included, the fastening can be suppressed from becoming loose.

### Fifth Embodiment

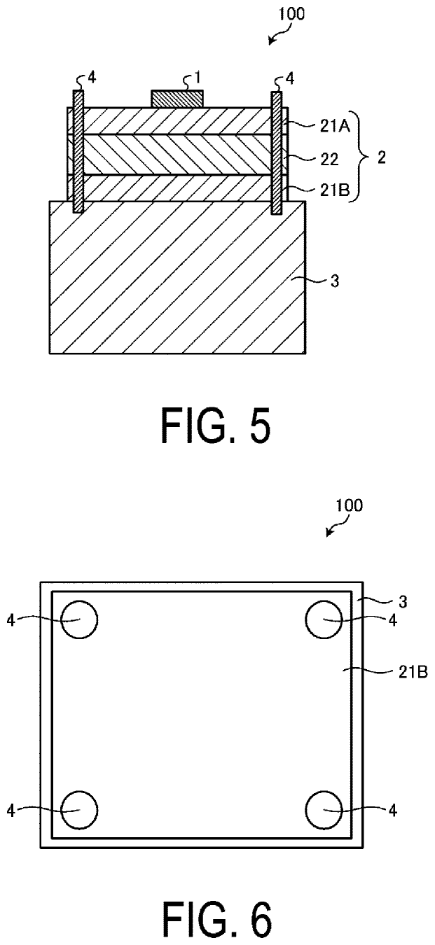

FIG. 5 is a schematic cross-sectional view illustrating a configuration example of the superconducting device 100 according to a fifth embodiment. FIG. 6 is a schematic plan view illustrating a positional relationship between a second organic layer 21B and the fixing member 4 according to the fifth embodiment. As illustrated in FIG. 5, the organic layer 21 of the stage portion 2 may include a first organic layer 21A located between the superconducting element 1 and the ceramic layer 22, and the second organic layer 21B located at the opposite side to the first organic layer 21A with the ceramic layer 22 interposed therebetween. According to such a configuration, since the organic layer 21 is disposed on both surfaces of the ceramic layer 22, the organic layer 21 can serve as a buffer material of the fixing member 4. When a surface area of the stage portion 2 is large, problems such as a distortion in the base 3 and the stage portion 2 may occur due to the stress generated between the base 3 and the stage portion 2. According to the superconducting device 100 of the fifth embodiment, the second organic layer 21B serves as a thermal and mechanical buffer material with respect to the base 3, and the occurrence of such problems can be reduced.

The second organic layer 21B located between the ceramic layer 22 and the base 3 may be a buffer material made of a material other than an organic material. In this case, the Young's modulus of the buffer material is preferably lower than the Young's modulus of the ceramic layer 22 constituting the stage portion 2. The Young's modulus of the buffer material is preferably lower than that of the material constituting the base 3.

### Variation of Fifth Embodiment

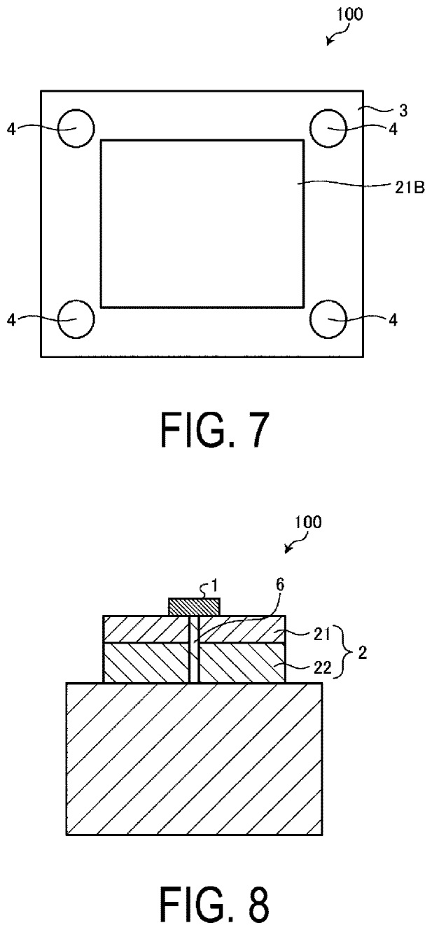

FIG. 7 is a schematic plan view illustrating a positional relationship between the second organic layer 21B and the fixing member 4 according to a variation the fifth embodiment.

As illustrated in FIG. 6, the second organic layer 21B may have a surface area covering the entire surface of the stage portion 2 at the base 3 side except for a through hole, or as illustrated in FIG. 7, the second organic layer 21B may be disposed only in a region except for the fixing member 4 immediately below the superconducting element 1. Alternatively, the second organic layer 21B may have a shape surrounding a region immediately below the superconducting element 1 in a frame shape. In this case, since another member such as the fixing member 4 is not interposed between the stage portion 2 and the base 3, the effect of relaxing the stress between the two can be enhanced while maintaining the thermal conductivity from the superconducting element 1 to the base 3.

### Sixth Embodiment

FIG. 8 is a schematic cross-sectional view illustrating a configuration example of the superconducting device 100 according to a sixth embodiment. As illustrated in FIG. 8, the superconducting device 100 may have a superconducting film 6 in contact with part of the organic layer 21 or part of the ceramic layer 22. The superconducting element 1 is electrically connected to the stage portion 2 via the superconducting film 6. As illustrated in FIG. 8, the superconducting film 6 may have a via structure penetrating through the organic layer 21 and the ceramic layer 22 constituting the stage portion 2 in the thickness direction. The material of the superconducting film 6 may contain at least one selected from the group consisting of mercury, vanadium, lead, niobium, niobium-titanium, niobium-tin, niobium-aluminum, vanadium-gallium, and magnesium-boron.

According to the superconducting device 100 of the sixth embodiment, since the stage portion 2 includes the superconducting film 6, the superconducting film 6 does not become a resistance at an extremely low temperature and can reduce a noise. Since the superconducting film 6 has a via structure, the inductance of a circuit in the stage portion 2 can be reduced.

### Seventh Embodiment

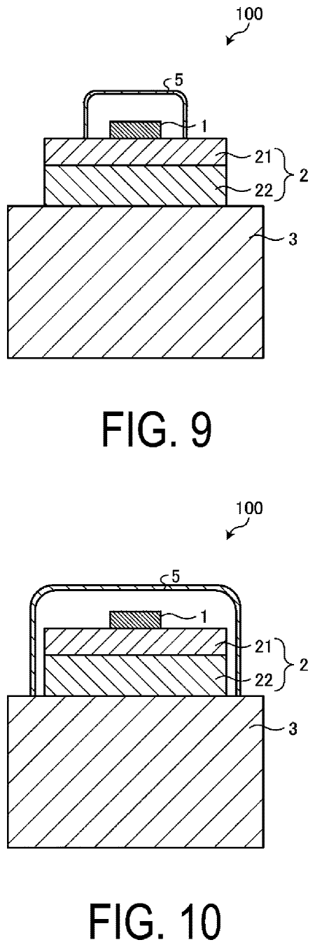

Each of FIGS. 9 and 10 is a schematic cross-sectional view illustrating a configuration example of the superconducting device 100 according to a seventh embodiment. As illustrated in FIGS. 9 and 10, the superconducting device 100 may include a cap 5 fixed to the stage portion 2 or the base 3. In this case, the superconducting element 1 is disposed in a region inside the cap 5. FIG. 9 illustrates an example in which the cap 5 is fixed to the organic layer 21 of the stage portion 2, and FIG. 10 illustrates an example in which the cap 5 is fixed to the base 3.

### Other Embodiment

In the above-described embodiment, the example in which the superconducting device 100 includes the superconducting element 1 has been described, but the element included in the superconducting device 100 is not limited thereto. For example, a quantum element such as a Josephson element, a silicon quantum bit element, an ion trap element, or an optical element may be included.

The above-described superconducting device can be produced by preparing the superconducting element 1, the stage portion 2, and the base 3, and laminating and bonding them to each other so as to have a desired arrangement. In this case, the stage portion 2 is produced by, for example, attaching an uncured organic layer (precursor) to the surface of the ceramic layer 22 that has already become a sintered body and performing a pressurizing and heating treatment. The organic layer 21 becomes the cured organic layer 21 when an uncured sheet-shaped mold is subjected to the heating and pressurizing treatment. The uncured sheet-shaped mold and the organic layer 21 contain organic resin as a main component. Epoxy resin is suitable as the organic resin. The uncured sheet-shaped mold and the organic layer 21 may contain an inorganic filler in addition to the organic resin. As the inorganic filler, silica or alumina can be selected. In particular, silica is suitable because of its low specific gravity.

As described later, the uncured sheet-shaped mold and the organic layer 21 may contain carbon particles. The content of the inorganic filler in the uncured sheet-shaped mold and the organic layer 21 is preferably from 1 volume % to 50 volume %. The content of the carbon particles in the uncured sheet-shaped mold and the organic layer 21 is preferably from 1 volume % to 30 volume %. The remainder excluding the contents of the inorganic filler and the carbon particles is the organic resin. The organic layer 21 of the disclosure may be a material of a two-component system in which the inorganic filler is added to the organic resin, but may be preferably a three-component system in which some of the inorganic fillers are replaced with the carbon particles for the reason described below. In this way, the organic layer 21 can maintain a state of being more easily elastically deformed than the ceramic layer 22.

As the ceramic layer 22, an alumina sintered body or a glass ceramic sintered body is preferably used. In this case, the ceramic layer 22 may have a structure including a conductor (wiring, via conductor) on the surface (main surface) and/or inside the ceramic layer 22. Since the organic layer 21 is attached to the entire surface of one main surface of the ceramic layer 22, a stress caused by the coefficient of thermal expansion and the Young's modulus is usually generated between the both layers. In the case of the stage portion 2 of the disclosure, since the organic layer 21 and the ceramic layer 22 are attached to each other over the entire surfaces of the main surfaces thereof, the organic layer 21 serves to reduce the amount of strain generated in the ceramic layer 22 due to a temperature change. On the other hand, the ceramic layer 22 also serves, to the organic layer 21, to reduce the amount of strain generated in the organic layer 21 due to the temperature change. In this case, the amounts of deformation of the organic layer 21 and the ceramic layer 22 caused by thermal expansion are less than that when the both layers are present as single bodies. The organic layer 21 and the ceramic layer 22 are not bonded to each other via any other material. Since the organic layer 21 and the ceramic layer 22 are in direct contact with each other on the entire surfaces of the main surfaces thereof and are bonded to each other, a binding force between the both layers can be increased. Since the thermal conductivity between the both layers can be increased, the organic layer 21 and the ceramic layer 22 can cause the inherent physical properties of each layer to act as a binding force even in an environment in which the temperature rapidly changes.

The organic layer 21 preferably contains carbon particles as the inorganic fillers. The carbon particles themselves have a lower Young's modulus than metal oxides such as alumina or silica. Even in a process in which the organic layer 21 is exposed to an environment of a low temperature, an increase in the Young's modulus can be suppressed between the carbon particles and the organic resin in the periphery of the carbon particles.

When the through hole is formed in the stage portion 2, any method selected from the group consisting of punching, drilling, laser, and the like is preferably used. In this case, a hole is preferably formed in the ceramic layer 22 when the ceramic layer 22 is in a state of a green sheet before firing. A hole may be formed in the organic layer 21 in advance when the organic layer 21 is in an uncured state, or may be formed after curing.

In one embodiment, (1) a superconducting device (as an example, superconducting device 100) includes a superconducting element (as an example, the superconducting element 1) and a stage portion (as an example, the stage portion 2). The superconducting element is located at the stage portion. The stage portion is a laminate body of a ceramic layer (as an example, the ceramic layer 22) and an organic layer (as an example, the organic layer 21).

(2) The superconducting device according to (1) may further include a base made of a metal, the stage portion being located at the base, the ceramic layer may be located at the base side, and the organic layer may be located at the superconducting element side.

(3) In the superconducting device according to (1), a thickness of the ceramic layer may be greater than a thickness of the organic layer.

(4) The superconducting device according to (1) or (2) may include a base including a recessed portion, and the stage portion may be located in the recessed portion.

(5) In the superconducting device according to (4), an entirety of the stage portion may be accommodated in the recessed portion.

(6) The superconducting device according to any one of (1) to (3) may further include a base, the stage portion being located at the base, and a fixing member that fixes the organic layer of the stage portion and the base to each other.

(7) In the superconducting device according to (6), the base may include a recessed portion, and the ceramic layer of the stage portion may be located in the recessed portion.

(8) In the superconducting device according to (1), the organic layer may include a first organic layer located between the superconducting element and the ceramic layer, and a second organic layer located at an opposite side to the first organic layer with the ceramic layer interposed therebetween.

(9) The superconducting device according to any one of (1) to (8) may include a superconducting film in contact with part of the organic layer or part of the ceramic layer.

The disclosure may be a quantum element device including the above-described quantum element instead of the superconducting element. More specifically, the quantum element device includes a quantum element selected from the group consisting of a Josephson element, a silicon quantum bit element, an ion trap element, and an optical element and a stage portion at which the quantum element is located, and the stage portion is a laminate body of a ceramic layer and an organic layer.

The quantum element device may include a base made of a metal, the stage portion being located at the base, the ceramic layer may be located at the base side, and the organic layer may be located at the quantum element side.

In the quantum element device, a thickness of the ceramic layer may be greater than a thickness of the organic layer.

The quantum element device may include a base including a recessed portion, and the stage portion may be located in the recessed portion.

The quantum element device may have a structure in which the entirety of the stage portion is accommodated in the recessed portion.

The quantum element device may have a structure including a base, the stage portion being located at the base and a fixing member for fixing the organic layer to the base.

In the quantum element device, the base may include a recessed portion, and the ceramic layer of the stage portion may have a structure of being located in the recessed portion.

In the quantum element device, the organic layer may have a structure including a first organic layer located between the superconducting element and the ceramic layer and a second organic layer located at the opposite side to the first organic layer with the ceramic layer interposed therebetween.

The quantum element device may have a structure including a superconducting film in contact with part of the organic layer or part of the ceramic layer.

It is needless to say that each drawing in FIGS. 1 to 10 (including each member constituting the superconducting device in each drawing) can be applied as a schematic structure of the quantum element device. In this case, the superconducting element (reference sign 1) in FIGS. 1 to 10 (except for FIGS. 6 and 7) is replaced with the above-described quantum element (quantum element 1).

In the above-described quantum element device, depending on the selected quantum element, the operating temperature may be set higher as compared with a case of using the superconducting element 1. Examples of the operating temperature include a temperature around room temperature (from −30° C. (243K) to 30° C. (303K)). In the case of using the quantum element operating near room temperature, it cannot be said that the environment is harsh in terms of temperature as compared with the case of using the superconducting element 1. However, in the case of a device operating near room temperature, there is a high possibility that the temperature change becomes greater than the extremely low temperature at which the superconducting element 1 is placed. This greater temperature change is likely to cause cracks in the substrate. The stage portion 2 of the disclosure can also cope with the problem caused by such a state change of the device to which the quantum element is applied.

The stage portion 2 of the disclosure can be used in the same or similar manner as in the case of using the Josephson element even in the case of using the quantum element whose operating temperature is higher than the boiling point of liquid helium (−269° C. (4K)) and lower than the boiling point of liquid nitrogen (−196° C. (77K)).

Note that the embodiments disclosed herein are exemplary in all respects and not restrictive. The aforementioned embodiments can be embodied in a variety of forms. The above-described embodiments may be omitted, substituted or modified in various forms without departing from the scope and spirit of the appended claims.

### REFERENCE SIGNS

1 Superconducting element
2 Stage portion
3 Base
4 Fixing member
5 Cap
6 Superconducting film
21 Organic layer
22 Ceramic layer
31 Recessed portion
100 Superconducting device

1. A superconducting device comprising:
a superconducting element;
a stage portion at which the superconducting element is located, wherein
the stage portion is a laminate body of a ceramic layer and an organic layer.

2. The superconducting device according to claim 1, further comprising:
a base made of a metal at which the stage portion is located, wherein
the ceramic layer is located at the base side, and
the organic layer is located at the superconducting element side.

3. The superconducting device according to claim 1, wherein
a thickness of the ceramic layer is greater than a thickness of the organic layer.

4. The superconducting device according to claim 1, further comprising:
a base comprising a recessed portion, wherein
the stage portion is located in the recessed portion.

5. The superconducting device according to claim 4, wherein
an entirety of the stage portion is accommodated in the recessed portion.

6. The superconducting device of claim 1, further comprising:
a base at which the stage portion is located; and
a fixing member configured to fix the organic layer to the base.

7. The superconducting device according to claim 6, wherein
the base comprises a recessed portion, and
the ceramic layer of the stage portion is located in the recessed portion.

8. The superconducting device of claim 1, wherein
the organic layer comprises
a first organic layer located between the superconducting element and the ceramic layer, and
a second organic layer located at an opposite side to the first organic layer with the ceramic layer interposed therebetween.

9. The superconducting device according to claim 1, further comprising:
a superconducting film in contact with part of the organic layer or part of the ceramic layer.
